(19) United States
(12) Patent Application Publication
(10) Pub. No.: US 2008/0158793 A1
(43) Pub. Date: Jul. 3, 2008

(54) Vertical electronic packaging

(76) Inventors: Joe A. Harrison, Olympia, WA (US); Richard E. Conlee, Milwaukie, OR (US); Timothy J. Cox, Olympia, WA (US)

Correspondence Address: INTEL CORPORATION;c/o INTELLEVATE, LLC, P.O. BOX 52050, MINNEAPOLIS, MN, 55402, US

(21) Appl. No.: 11/647,776

(22) Filed: Dec. 28, 2006

(51) Int. Cl. H05K 5/00

(52) U.S. Cl. 361/679; 361/829

(57) ABSTRACT

In some embodiments a holder holds an electronic device at a distance from a board and couples the electronic device to the board. One or more legs stabilize and provide 360 degree support for the electronic device in a z-axis height away from the board. Other embodiments are described and claimed.

### TECHNICAL FIELD

The inventions generally relate to vertical electronic packaging.

### BACKGROUND

Current packaging solutions for attaching a device on a board such as a printed circuit board (PCB) and/or a motherboard in a manner that the device is vertically positioned away from the board include a package with leads crimped into female contacts that are placed in a two position housing. The assembly is covered with heat shrink to help protect and support the delicate device. This assembly is then inserted vertically onto a two pin header. However, two pin headers and mating assemblies typically have been very unstable with intermittents. Additionally, this type of arrangement requires three interconnect levels including a device (for example, a transistor) to crimped contacts level, contacts to pin header level, and header to motherboard level.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates an apparatus according to some embodiments of the inventions.

FIG. 2 illustrates an apparatus according to some embodiments of the inventions.

FIG. 3 illustrates an apparatus according to some embodiments of the inventions.

FIG. 4 illustrates an apparatus according to some embodiments of the inventions.

### DETAILED DESCRIPTION

Some embodiments of the inventions relate to vertical electronic packaging.

In some embodiments a holder holds an electronic device at a distance from a board and couples the electronic device to the board. One or more legs stabilize and provide 360 degree support for the electronic device in a z-axis height away from the board.

In some embodiments a system includes an electronic device, a board, and a holder. The holder holds the electronic device at a distance from the board and couples the electronic device to the board. The holder also stabilizes and provides 360 degree support for the electronic device in a z-axis height away from the board.

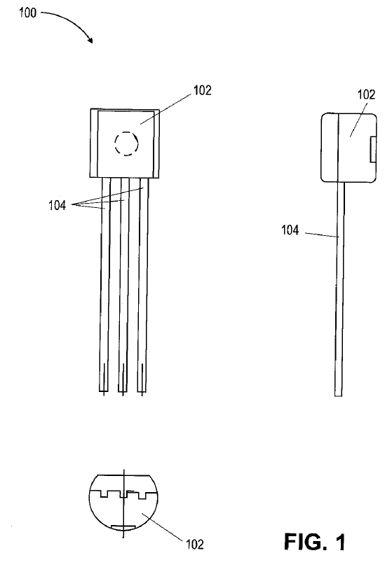

FIG. 1 illustrates an apparatus 100 according to some embodiments. In some embodiments apparatus 100 includes a device 102 and leads 104. FIG. 1 illustrates the apparatus 100 in a side view (left top side of FIG. 1), an end view (right side of FIG. 1), and a top view (left bottom of FIG. 1). In some embodiments, apparatus 100 is a vertical packaging solution that keeps the device 102 off the motherboard in the Z axis. This can allow, for example, the device to act as a thermal diode in circuitry for controlling system fan monitoring, for example. In some embodiments, apparatus 100 includes a device 102 that is a transistor (for example, a TO-92 transistor).

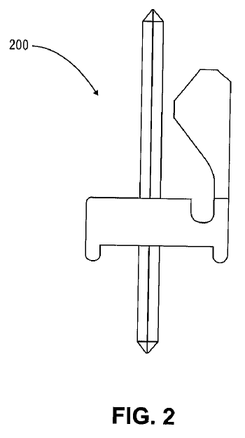

FIG. 2 illustrates an apparatus 200 according to some embodiments. In some embodiments apparatus 200 is a two pin header shown in a side view. In some embodiments, for example, apparatus 200 is a two pin header located on a Balanced Technology Extended (BTX) form factor and/or a uBTX form factor.

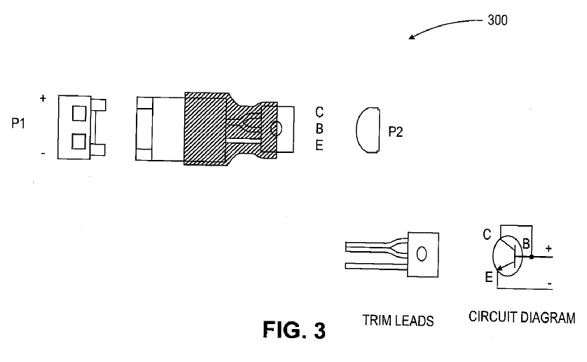

FIG. 3 illustrates an assembly 300 according to some embodiments. In some embodiments assembly 300 plugs into a two pin header such as the apparatus 200 illustrated in FIG. 2.

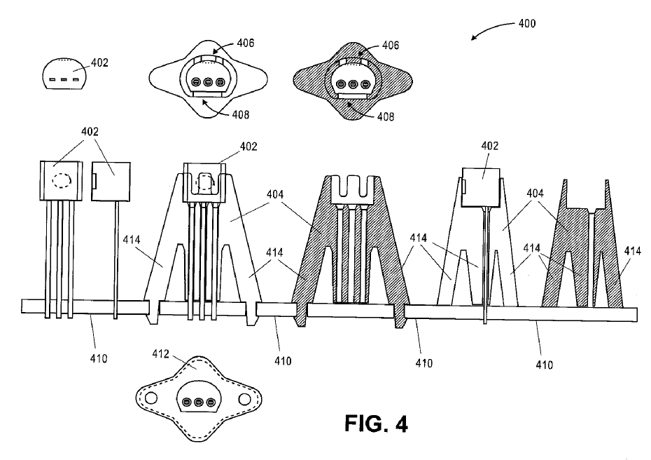

FIG. 4 illustrates an apparatus 400 according to some embodiments. FIG. 4 includes an illustration of a device 402 (for example, a TO-92 device and/or a thermal diode sensor) in a side view, an end view, and a top view (all at the left side of FIG. 4). FIG. 4 further includes an illustration of a top view, a side view, a PCB layout view, and an end view of apparatus 400 with device 402 inserted. FIG. 4 also includes an illustration of a top view, a side view, a PCB layout view, and an end view of apparatus 400 with no device inserted.

In some embodiments apparatus 400 includes device 402 and vertical holder 404. In some embodiments vertical holder 404 is a plastic holder (for example, using thermoplastic polycarbonate, General Electrical Corp. material LEXAN 940, and/or having a minimum UL94 flammability rating of V-2). In some embodiments vertical holder 404 provides stabilization and/or 360 degree support in z-axis height. In some embodiments holder 404 includes a positive seating retention feature to hold device 402 in the holder 404. For example, in some embodiments holder 404 includes a device retention tab 406 to provide a positive seating retention to hold device 402 in the holder 404. In some embodiments holder 404 includes a window 408 in holder 404 to allow air flow to make contact with the device 402. In some embodiments holder 404 includes a stabilizing support on the board 410 to which the device 402 and the holder 404 are attached. In some embodiments, board 410 is a printed circuit board such as a motherboard, for example. In some embodiments holder 404 includes legs 414 (including outer legs and/or middle legs as illustrated in FIG. 4, for example). In some embodiments, legs 414 are support legs used to stabilize device 402 in a 360 degree area, for example. In some embodiments, legs 414 are made to extend through a board 410, for example.

In some embodiments, apparatus 400 consists of a plastic holder for a vertical packaging solution to provide height, support, and/or stability to an electronic device (for example, an industry standard device). In some embodiments apparatus 400 allows for a vertical packaging solution to allow a package (for example, an industry standard package) to stand off the board (for example, motherboard) in a manner that it is arranged in system airflow in order to provide feedback to system monitoring circuitry (for example, to determine temperature within the system to get a good temperature reading without being too close to the board). In some embodiments, for example, the device 402 may act as a thermal diode in circuitry for control of system fan monitoring. In some embodiments, electronic device 402 acts as a portion of a thermal detection circuit to provide feedback relating to system thermal and/or other variables (for example, to a system monitoring circuit of a computer system in which the apparatus 400 is included).

In some embodiments a vertical plastic package contains an industry standard package. In some embodiments, for example, a package includes a retention feature to hold a device (for example, an industry standard device) in a plastic holder before being wave soldered. In some embodiments the optimized retention includes a user feedback feature to ensure positive seating (for example, a device retention tab). In some embodiments a window allows unrestricted system air flow to a device. In some embodiments support legs of a holder allow a device to be stabilized in a 360 degree area.

In some embodiments, a single interconnect is used for a vertical electronic package (for example, as illustrated in FIG. 4). Use of a single interconnect removes two extra levels of interconnect to the circuit design. This solution provides a board component solution rather than a system component that is installed after the motherboard is assembled, for example. This helps to remove a discrete assembly that needs to be ordered, tracked, installed, etc. in the system. In some embodiments, a package is used that lowers the cost of each location where a device is used. For example, the cost may be lowered by approximately 21 cents per each location where a thermal sensor diode is used.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. An apparatus comprising:
a holder to hold an electronic device at a distance from a board and to couple the electronic device to the board; and
one or more legs to stabilize and to provide 360 degree support for the electronic device in a z-axis height away from the board.

2. The apparatus of claim 1, further comprising a positive seating retention mechanism to retain the electronic device in the holder.

3. The apparatus of claim 1, further comprising a window to allow air flow to make contact with the electronic device while it is held in the holder.

4. The apparatus of claim 1, wherein the board is a printed circuit board.

5. The apparatus of claim 1, wherein the one or more legs extend through the board.

6. The apparatus of claim 1, wherein the electronic device is a thermal diode sensor.

7. A system comprising:
an electronic device;
a board;
a holder to hold the electronic device at a distance from the board and to couple the electronic device to the board, and to stabilize and to provide 360 degree support for the electronic device in a z-axis height away from the board.

8. The system of claim 7, the holder further including one or more legs to stabilize and to provide the 360 degree support for the electronic device in the z-axis height away from the board.

9. The system of claim 7, the holder further comprising a positive seating retention mechanism to retain the electronic device in the holder.

10. The system of claim 7, the holder further comprising a window to allow air flow to make contact with the electronic device while it is held in the holder.

11. The system of claim 7, wherein the board is a printed circuit board.

12. The system of claim 7, wherein the one or more legs extend through the board.

13. The system of claim 7, wherein the electronic device is a thermal diode sensor.

14. The system of claim 7, further comprising a thermal detection circuit to provide thermal monitoring of the system in response to the electronic device.
